(19) United States
(12) Patent Application Publication
(10) Pub. No.: US 2008/0304219 A1
(43) Pub. Date: Dec. 11, 2008

(54) LIGHT EMITTING DIODE DISPLAY

(75) Inventor: Yu-Chu Chen, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AMA PRECISION INC., Taipei (TW)

(21) Appl. No.: 12/134,203

(22) Filed: Jun. 6, 2008

(30) Foreign Application Priority Data
Jun. 8, 2007 (TW) 96120700

(51) Int. Cl. H05K 7/14

(52) U.S. Cl. 361/681

(57) ABSTRACT

An LED display includes a fixing frame and a plurality of LED modules. The fixing frame has at least one rotating shaft. The LED modules are correspondingly pivoted on the rotating shaft, and each of the LED modules is adapted to rotate around the corresponding rotating shaft. The LED modules can be easily disassembled from the fixing frame for repair.

### CROSS-REFERENCE TO RELATED APPLICATION

This application claims the priority benefit of Taiwan application serial no. 96120700, filed on Jun. 8, 2007. The entirety of the above-mentioned patent application is hereby incorporated by reference herein and made a part of this specification.

### BACKGROUND OF THE INVENTION

1. Field of the Invention

The invention relates to a light emitting diode (LED) display and, more particularly, to an LED display easily assembled or disassembled.

2. Description of the Related Art

As the semiconductor technology develops, the size of a display tends to be large. The common display usually includes a household planar display, such as a liquid crystal display (LCD), a plasma display panel (PDP) and so on, and an LED display for a large-sized outdoor billboard.

In the large-sized outdoor billboard, a plurality of LED modules are often arranged in array to form the LED display presenting the needed size. FIG. 1 is a schematic diagram showing part of a conventional LED display. Please refer to FIG. 1. A fixing frame 110 of the LED display 100 has sliding rails 112 in which LED modules 120 are slidingly disposed. In detail, when the LED modules 120 are assembled to the fixing frame 110, the block-shaped LED modules 120 are placed between two sliding rails 112 one by one, and then the LED modules 120 can be stacked from the bottom to the top of the fixing frame 110. The LED modules 120 can be easily assembled to the fixing frame 110 by the sliding rails 112.

However, when one of the LED modules 120 in the LED display 100 is damaged, it is difficult to only disassemble the damaged one for repair. The damaged one can be disassembled for replacement or repair only when the undamaged ones above the damaged one are removed from the sliding rail 112 one by one. It prolongs the disassembling time, and does not facilitate the replacement or repair of the LED modules 120.

### BRIEF SUMMARY OF THE INVENTION

An objective of the invention is to provide an LED display easily disassembled for replacement or repair.

The invention provides an LED display including a fixing frame and a plurality of LED modules. The fixing frame has at least one rotating shaft. The LED modules are correspondingly pivoted on the rotating shaft, and each of the LED modules is adapted to rotate around the corresponding rotating shaft.

In a preferred embodiment, the fixing frame includes a plurality of first frame ribs and a plurality of second frame ribs perpendicular to the first frame ribs. The first frame ribs and the second frame ribs join to form a plurality of containing spaces.

In a preferred embodiment, the first frame ribs and the rotating shaft are integrally formed.

In a preferred embodiment, the second frame ribs and the rotating shaft are integrally formed.

In a preferred embodiment, the LED modules are correspondingly disposed in the containing spaces.

In a preferred embodiment, the material of the fixing frame is metal.

In a preferred embodiment, each of the LED modules includes a holding portion disposed on one side edge of the LED module, and the holding portion is held with a mechanical arm for moving the LED module.

In a preferred embodiment, the holding portion is a ring.

In a preferred embodiment, the LED display further includes a plurality of pivoting elements disposed between the LED modules and the corresponding rotating shaft.

In a preferred embodiment, the pivoting elements are rivets.

In a preferred embodiment, the LED display further includes a plurality of locking elements for locking the LED modules to the fixing frame.

The invention further provides an LED display including a fixing frame and a plurality of LED modules. The fixing frame includes a rim, a plurality of first frame ribs, and a plurality of second frame ribs. The first frame ribs and the second frame rib are perpendicular to one another. The rim, the first frame ribs, and the second frame ribs join to form a plurality of containing spaces. At least one LED module is correspondingly disposed in one containing space. The LED module is pivoted on one of the first frame ribs, the second frame ribs, or the rim, and it is adapted to rotate around the corresponding first frame rib, the second frame rib, or the rim.

In a preferred embodiment, the rim, the first frame ribs, and the second frame ribs are integrally formed.

In a preferred embodiment, the LED modules are correspondingly disposed in the containing spaces.

In a preferred embodiment, the material of the rim, the first frame ribs, and the second frame ribs is metal.

In a preferred embodiment, each of the LED modules further includes a holding portion disposed on one side edge of the LED module, and the holding portion is held with a mechanical arm for moving the LED module.

In a preferred embodiment, the holding portion is a ring.

In a preferred embodiment, each of the LED modules further includes a plurality of pivoting elements disposed between the LED modules and the corresponding first frame rib, the second frame rib, or the rim.

In a preferred embodiment, the pivoting elements include rivets.

In a preferred embodiment, the LED display further includes a plurality of locking elements for locking the LED modules to the fixing frame.

In the LED display according to the invention, a single LED module can be assembled to or disassembled from the fixing frame by being rotated around the rotating shaft of the fixing frame. Therefore, the damaged LED modules can be conveniently disassembled from the fixing frame for repair or replacement.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1 is a schematic diagram showing part of a conventional LED display.

FIG. 2A and FIG. 2B are schematic diagrams showing an LED display from two different angles according to an embodiment of the invention.

FIG. 3 is a schematic diagram showing part of a fixing frame according to another embodiment of the invention.

FIG. 4 is a schematic diagram showing an LED module and a pivoting element.

FIGS. 5A-5C are flow charts sequentially showing the assembling process of an LED display.

FIG. 6 is a schematic diagram showing an LED display according to a second embodiment of the invention.

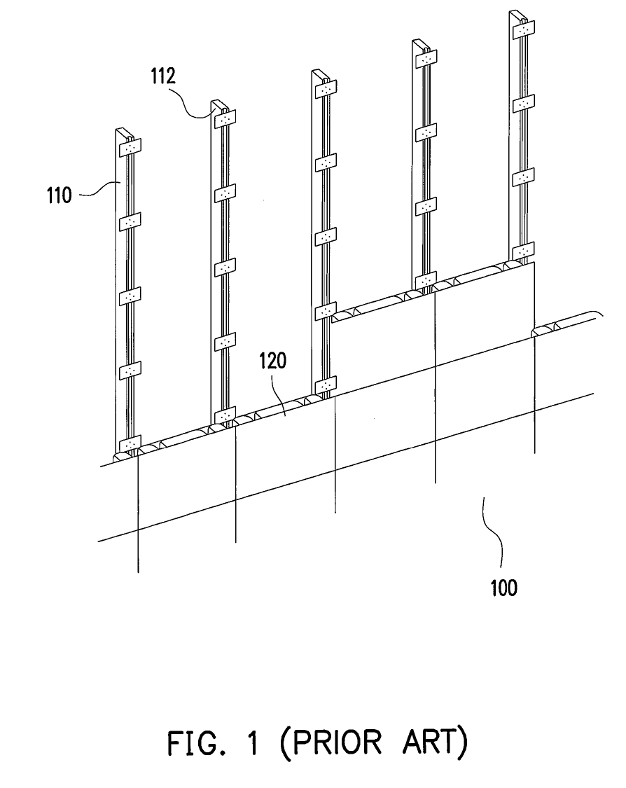

### DETAILED DESCRIPTION OF THE EMBODIMENTS

### First Embodiment

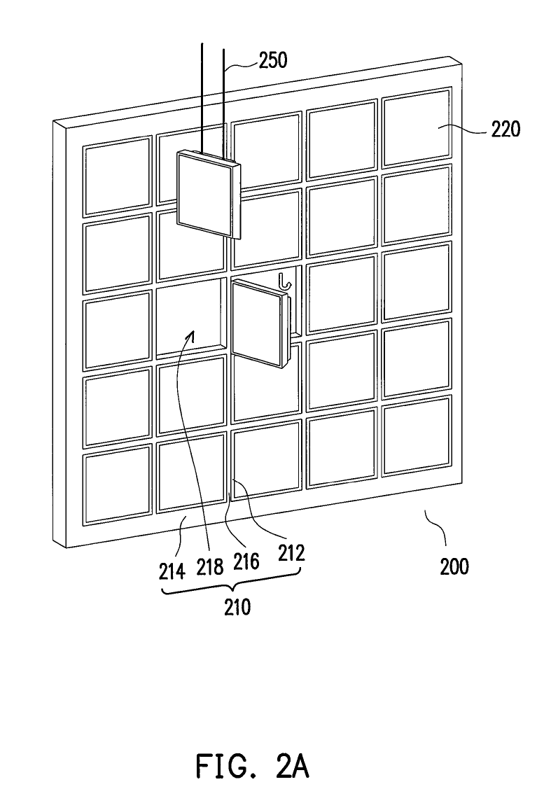

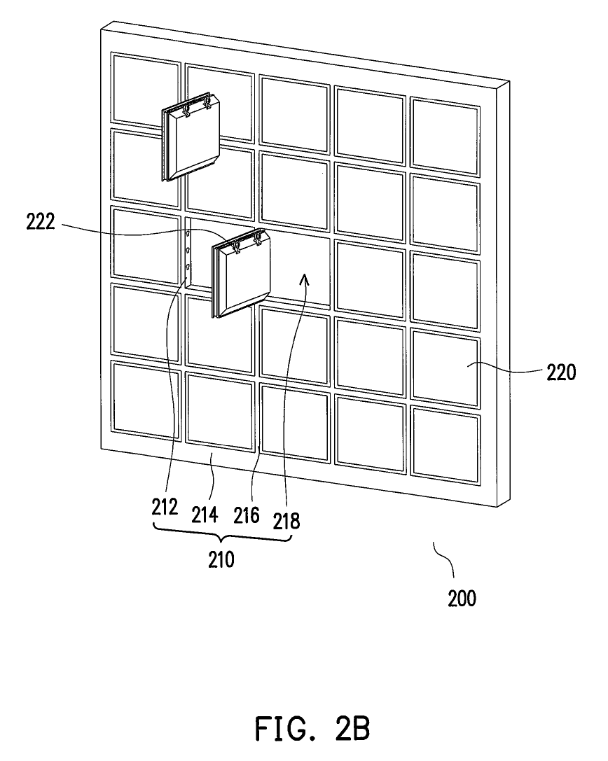

FIG. 2A and FIG. 2B are schematic diagrams showing an LED display from two different angles according to an embodiment of the invention. Please refer to FIG. 2A and FIG. 2B together. The LED display 200 includes a fixing frame 210 and a plurality of LED modules 220. The fixing frame 210 has at least one rotating shaft 212. The LED modules 220 are correspondingly pivoted on the rotating shaft 212 and are adapted to rotate around the corresponding rotating shaft 212 to be fastened to the fixing frame 210.

In detail, the fixing frame 210 may include a plurality of first frame ribs 214 and a plurality of second frame ribs 216. The first frame ribs 214 are parallel to one another, and the second frame ribs 216 are also parallel to one another. The first frame ribs 214 and the second frame ribs 216 are perpendicular to one another to form a plurality of containing spaces 218. The LED modules 220 are correspondingly disposed in the containing spaces 218. The fixing frame 210 formed with the first frame ribs 214 and the second frame ribs 216 has many advantages. For example, when the size of the LED display 200 is modified by clients, the first frame ribs 214 and the second frame ribs 216 can be added to enlarge the LED display 200 at any time, or part of the first frame ribs 214 and the second frame ribs 216 can be disassembled to reduce the size of the LED display 200.

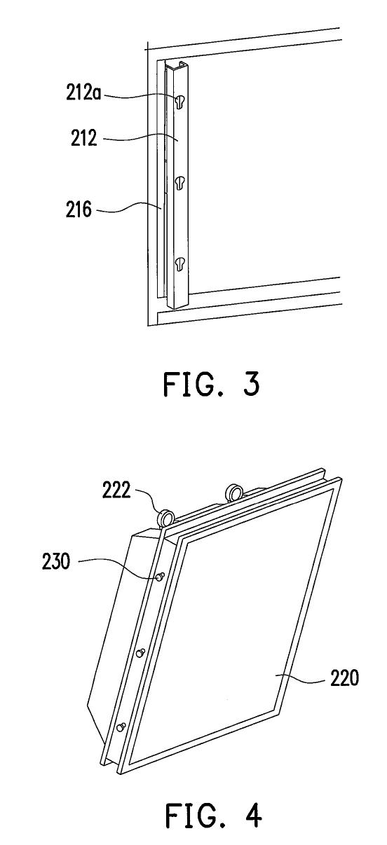

FIG. 3 is a schematic diagram showing part of a fixing frame according to another embodiment of the invention. In FIG. 3, the rotating shaft 212 is assembled to the second frame ribs 216 by post-processing. Further, the rotating shaft 212 also can be integrally formed with the the second frame ribs 216. Refer to FIG. 2A and FIG. 2B, the rotating shaft 212 may be assembled to the first frame ribs 214. It depends on consideration for manufacture costs of designers. Since the LED display 200 is applied in a large-sized outdoor billboard, some rigidity of the fixing frame 210 is required to support the plurality of LED modules 220. Therefore, the first frame ribs 214 and the second frame ribs 216 may be made of the material of high rigidity, such as metal.

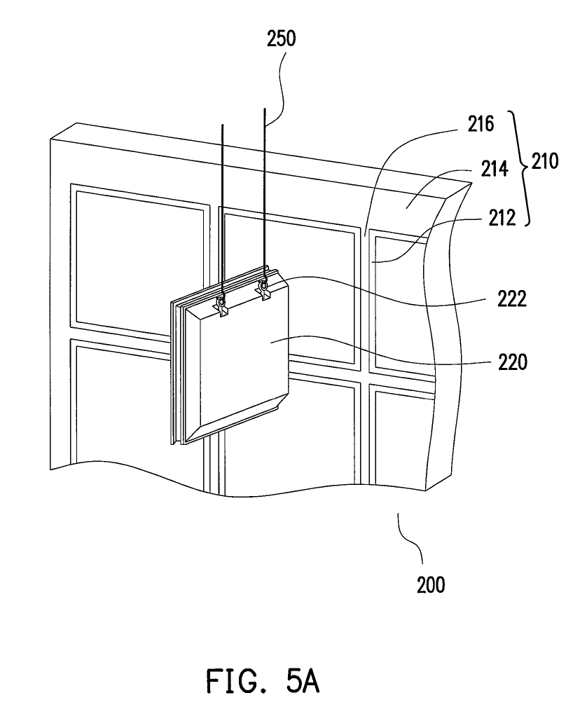

FIG. 4 is a schematic diagram showing an LED module and a pivoting element. When the LED display 200 of small size is required, the LED display 200 may be assembled manually. However, when the LED display 200 of large size is required, the manual assembling method may not be adopted. To facilitate the automatic assembling process of the LED display 200, the LED module 220 further has a holding portion 222 disposed on one side edge of the LED module 220, such as the upper side of the LED module 220. Refer to FIG. 2A and FIG. 2B, a mechanical arm 250 holds the holding portion 222 for moving the LED module 220 to be close to the fixing frame 210. The holding portion 222 may be a ring or other structure easily held by the mechanical arm 250.

The LED display 200 further includes a plurality of pivoting elements 230 for pivotally connecting the LED modules 220 to the rotating shaft 212. The pivoting elements 230 are disposed between the LED modules 220 and the rotating shaft 212. The pivoting element 230, such as rivets, is fastened to the LED modules 220. The rotating shaft 212 has holes 212a for receiving the rivets. The LED modules 220 can be assembled to the rotating shaft 212 by the pivoting elements 230. The material of the pivoting elements 230 can be metal for heat dissipation of the LED modules 220. However, since the first frame ribs 214 and the second frame ribs 216 are made of metal, it may damage the LED modules 220 because of the touch therebetween when the LED modules 220 is assembled. Therefore, to avoid this situation, the pivoting elements 230 can be made of resilient material such as plastic.

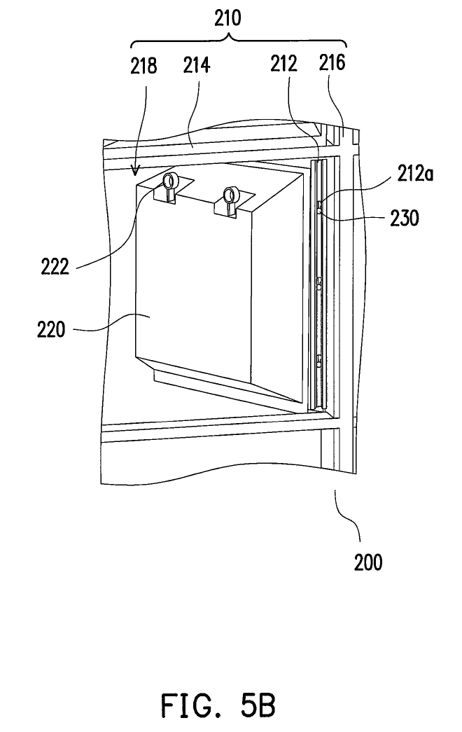

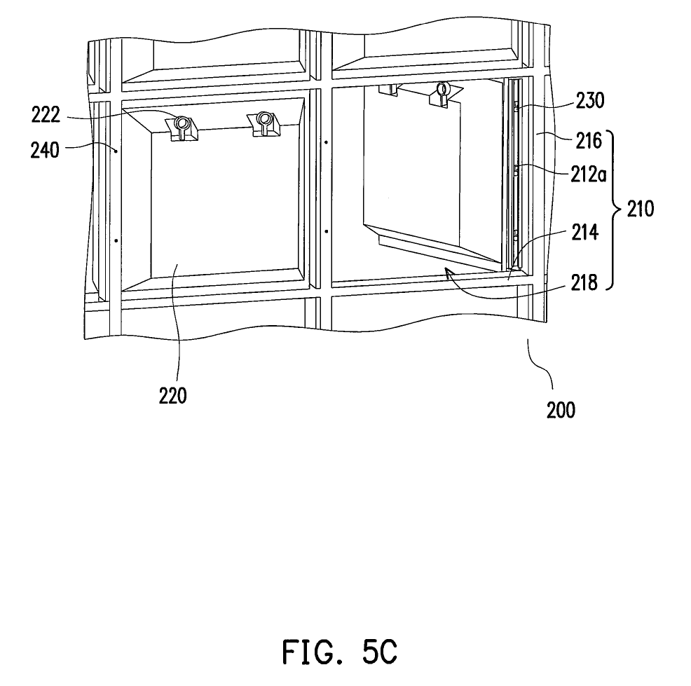

FIGS. 5A-5C are flow charts sequentially showing the assembling process of an LED display. First, in FIG. 5A, the mechanical arm 250 holds the holding portion 222 to move the LED modules 220 to be close to the fixing frame 210. Second, in FIG. 5B, the LED modules 220 are pivoted on the rotating shaft 212. Finally, in FIG. 5C, the LED modules 220 are moved to closely fit the pivoting element 230 with the first frame ribs 214 or the second frame ribs 216. Then the LED modules 220 are assembled to the fixing frame 210 and are disposed in the containing spaces 218.

From the above, it is easy to assemble the LED display 200 only by pivotal connecting, rotating, fastening and so on.

To prevent the LED modules 220 from falling off the fixing frame 210 because of the collision during the transportation or assembling process, a plurality of locking elements 240 can be used to lock the LED modules 220 to the fixing frame 210. The locking elements 240 may be, for example, screws. Regarding the elements for fastening the LED modules 220 to the fixing frame 210, it is not only limited to the locking elements 240 in the invention. The persons having ordinary skill in the art also can use hooks or other fastening elements to fasten the LED modules 220 to the fixing frame 210.

When a single LED module 220 is damaged, the fastening elements 240 can be first disassembled, and then the damaged one is rotated out of the fixing frame 210. Next, the damaged one is disassembled from the fixing frame 210. Compared with the prior art, the LED module 220 of the LED display 200 can be separately disassembled for replacement or repair, and the other LED modules 220 which operate properly keep the original states. Therefore, the damaged one can be easily disassembled for replacement, and thus the time is saved.

### Second Embodiment

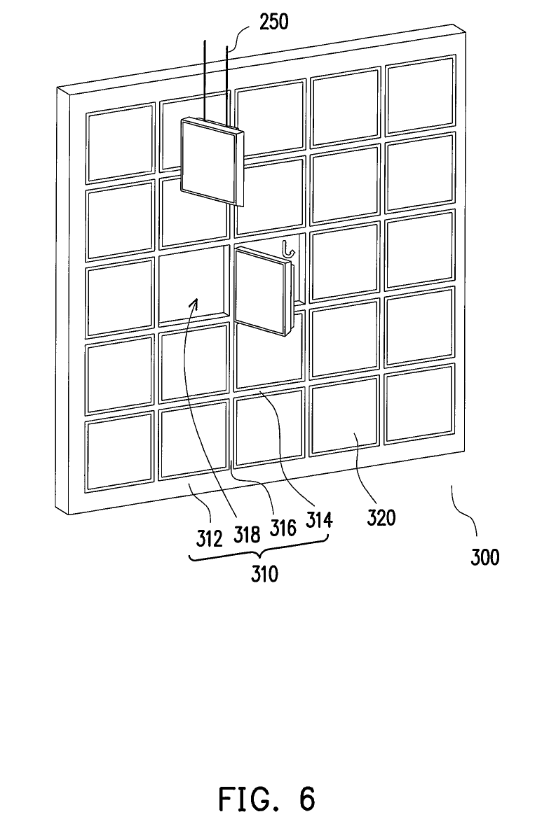

FIG. 6 is a schematic diagram showing an LED display according to a second embodiment of the invention. Please refer to the FIG. 2A and FIG. 6 together. This embodiment is the same to the first embodiment in substance, and the same or similar numbers denote the same or similar elements. The differences between this embodiment and the first embodiment lie in that the fixing frame 310 includes a rim 312, a plurality of first frame ribs 314, and a plurality of second frame ribs 316. The first frame ribs 314 and the second frame ribs 316 are perpendicular to one another. The rim 312, the first frame ribs 314, and the second frame ribs 316 form a plurality of containing spaces 318. Further, at least one LED module 320 is pivoted on the rim 312, the first frame rib 314, or the second frame rib 316 and is adapted to rotate around the corresponding the rim 312, the first frame rib 314, or the second frame rib 316.

Two LED modules 320 of the LED display 300 in FIG. 6 are assembled to the fixing frame 310 by being rotated around the second frame ribs 316. This assembling method has been described in the first embodiment, and therefore it is not repeated for concise purpose.

Further, the other LED modules 320 in FIG. 6 also can be assembled to the fixing frame 310 of the LED display 300 in other manners. For example, the LED modules 320 can closely fit with the corresponding rim 312, the first frame ribs 314, or the second frame ribs 316, or the LED modules 320 can be fastened to the rim 312, the first frame ribs 314, or the second frame ribs 316 by hooks. It is obvious for persons having ordinary skill in the art to adopt other methods to assemble the LED modules 320 to the fixing frame 310.

From the above, in the LED display 300 according to this embodiment, the LED modules 320 can be assembled to the fixing frame 310 in different manners, such as close fitting, fastening by hooks, sliding connecting, pivotal connecting, locking by locking elements and so on. The invention is not limited thereto.

From the above, the LED display according to the invention at least has the following advantages.

First, the fixing frame of the LED display is composed of frame ribs, and therefore after the LED display of a predetermined size is assembled, the frame ribs can be added or reduced to adjust the final size of the LED display according to demands. Accordingly, the size of the LED display can be adjusted at any time.

Second, the LED modules can be assembled to the fixing frame just by pivotal connecting, rotating, fastening and so on. These simple actions can reduce the assembling time and avoid mistakes. Further, this advantage of easy assembly can reduce the reassembling time.

Third, when part of the LED modules is damaged, it can be disassembled from the fixing frame for replacement by simple disassembling actions. Further, the undamaged LED modules may remain the original states. Therefore, it is easy to disassemble and replace the damaged LED modules, and thus the time is saved.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A light emitting diode (LED) display, comprising:
a fixing frame having at least one rotating shaft; and
a plurality of LED modules correspondingly pivoted on the rotating shaft.

2. The LED display according to claim 1, wherein the fixing frame comprises a plurality of first frame ribs and a plurality of second frame ribs perpendicular to the first frame ribs, and the first frame ribs and the second frame ribs form a plurality of containing spaces.

3. The LED display according to claim 2, wherein the first frame ribs and the rotating shaft are integrally formed.

4. The LED display according to claim 2, wherein the second frame ribs and the rotating shaft are integrally formed.

5. The LED display according to claim 2, wherein the LED modules are correspondingly disposed in the containing spaces.

6. The LED display according to claim 1, wherein the material of the fixing frame is metal.

7. The LED display according to claim 1, wherein each of the LED modules comprises a holding portion disposed on one side edge of the LED module, and the holding portion is held with a mechanical arm for moving the LED module.

8. The LED display according to claim 7, wherein the holding portion is a ring.

9. The LED display according to claim 1, wherein the LED display further comprises a plurality of pivoting elements disposed between the LED module and the corresponding rotating shaft.

10. The LED display according to claim 9, wherein the pivoting elements comprise rivets.

11. The LED display according to claim 1, wherein the LED display further comprises a plurality of locking elements for locking the LED modules to the fixing frame.

12. An LED display, comprising:
a fixing frame comprising a rim, a plurality of first frame ribs, and a plurality of second frame ribs, wherein the first frame ribs are perpendicular to the second frame ribs, and the rim, the first frame ribs, and the second frame ribs join to form a plurality of containing spaces; and
a plurality of LED modules, wherein one of the LED modules is correspondingly disposed in one of the containing spaces and is pivoted on one of the first frame ribs, the second frame ribs, and the rim.

13. The LED display according to claim 12, wherein the rim, the first frame ribs, and the second frame ribs are integrally formed.

14. The LED display according to claim 12, wherein the LED modules are correspondingly disposed in the containing spaces.

15. The LED display according to claim 12, wherein the material of the rim, the first frame ribs, and the second frame ribs is metal.

16. The LED display according to claim 12, wherein each of the LED modules comprises a holding portion disposed on one side edge of the LED module, and the holding portion is held with a mechanical arm for moving the LED module.

17. The LED display according to claim 16, wherein the holding portion is a ring.

18. The LED display according to claim 12, further comprises a plurality of pivoting elements disposed between the LED module and the corresponding first frame rib, the second frame rib, or the rim.

19. The LED display according to claim 18, wherein the pivoting elements comprise rivets.

20. The LED display according to claim 12, wherein the LED display further comprises a plurality of locking elements for locking the LED modules to the fixing frame.
